(19) United States
(12) Patent Application Publication
(10) Pub. No.: US 2003/0198358 A1
(43) Pub. Date: Oct. 23, 2003

(54) Loudspeaker arrangement and switching apparatus therefor

(76) Inventors: Alan Anderson Hoover, Indianapolis, IN (US); Robert Edward Morris, Indianapolis, IN (US); Mark Alan Simpson, Fishers, IN (US)

Correspondence Address: JOSEPH S. TRIPOLI, THOMSON MULTIMEDIAL LICENSING INC., 2 INDEPENDENCE WAY, P. O. BOX 5312, PRINCETON, NJ, 08543-5312, US

(21) Appl. No.: 10/126,743

(22) Filed: Apr. 19, 2002

(51) Int. Cl. H02B 1/00; H03F 21/00

(52) U.S. Cl. 381/123; 381/120; 381/59

(57) ABSTRACT

There is provided an acoustic sound reproducing apparatus for a first audio signal and having an input terminal for receiving a second audio signal, a selector switch and at least one loudspeaker. The at least one loudspeaker is driven by an output signal from one of the first or second audio signal through the selector switch. As a result, the acoustic sound reproducing apparatus, and the apparatus providing the second audio signal, can commonly use a single loudspeaker or set of loudspeakers. When the external audio signal is selected, the internal loudspeaker(s) becomes part of the external loudspeaker arrangement for a surround sound system. When more than one loudspeaker is used, the loudspeakers are connected to each other in series when they are connected to be driven by the external second audio input signal instead of each being driven by their respective amplifiers. This permits the loudspeakers to be driven by an external amplifier having a higher power output than the internal power amplifier so that the loudspeakers will not be damaged when driven by a higher power external amplifier.

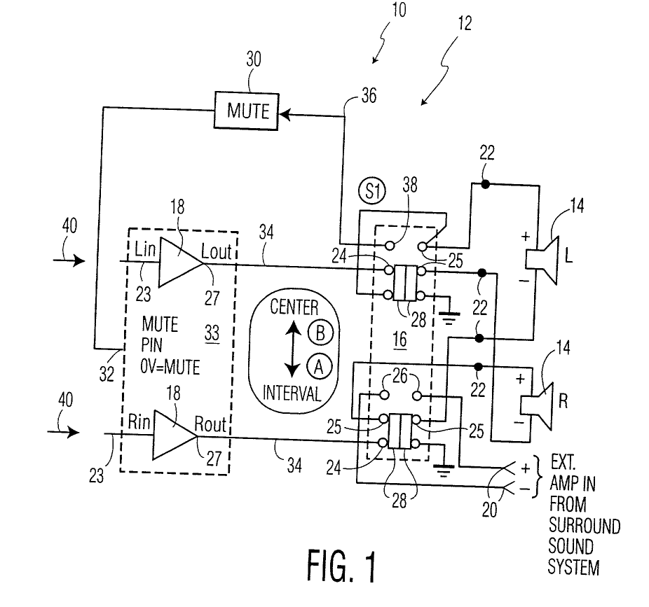

### FIELD OF THE INVENTION

The present invention relates generally to acoustic sound reproducing apparatus, and more particularly, to a loudspeaker arrangement and switching apparatus therefor.

### BACKGROUND

A television receiver with its loudspeakers, and an audio sound system with its loudspeakers, are often disposed in a common listening room with the two not generally operated at the same time because the user cannot simultaneously listen to both when each has its own program source. Thus, the utilization efficiency of each of the various loudspeakers is reduced. For example, if the audio signal is a stereophonic signal reproduced in a multidirectional surround sound system such as a Dolby™ 5.1 sound system, five loudspeakers are used with one of the loudspeakers being a center loudspeaker which receives an L+R signal. The television receiver, e.g., if it uses an MTS stereo system, has at least two loudspeakers. Thus, because both systems cannot be simultaneously listened to when each has its own program source, the space efficiency of the listening room is also reduced.

One such attempt to improve the utilization efficiency of the various loudspeakers and to improve the space efficiency of the listening room is shown in U.S. Pat. No. 5,329,371.

### SUMMARY OF THE INVENTION

There is provided an acoustic sound reproducing apparatus for a first audio signal and having an input terminal for a second audio signal, a selector switch and at least one loudspeaker. The at least one loudspeaker is driven by an output signal from one of the first or second audio signal through the selector switch. As a result, the acoustic sound reproducing apparatus, which in the exemplary embodiment is a television receiver, and the apparatus providing the second audio signal, which in the exemplary embodiment is a surround sound audio system, can commonly use a single loudspeaker or plurality of loudspeakers. When the external audio signal is selected, the at least one internal loudspeaker becomes part of the external loudspeaker arrangement for the surround sound system.

When more than one loudspeaker is used, the loudspeakers are connected to their respective amplifiers and are connected to each other in series when they are connected by the selector switch to be driven by the external second audio signal. This permits the loudspeakers to be driven by an external amplifier having a higher power output than the internal power amplifier, so that the loudspeakers will not be damaged when driven by such a higher power external amplifier. U.S. Pat. No. 4,146,745 shows loudspeakers connected in series.

### DESCRIPTION OF THE DRAWING

The FIGURE shows a block diagram and switch/loudspeaker arrangement according to aspects of the present invention

### DETAILED DESCRIPTION OF THE PREFERRED EMBODIMENT

The FIGURE shows a block diagram and switch/loudspeaker arrangement of an acoustic signal reproducing apparatus according to aspects of the present invention. The acoustic signal reproducing system of the present invention includes a television receiver 10 and an audio signal reproducing apparatus 12 including loudspeakers 14.

Apparatus 12 has a selector switch 16, amplifiers 18, an external input terminal 20 and an amplifier output terminal 27 coupling respective amplifier output signals to respective output leads 22, 34. The audio signal is supplied to input terminal 23 of respective amplifier 18 and respective output terminals 27 are connected to respective fixed terminals 24 of selector switch 16. Leads 22 coupled to respective loudspeakers 14, connect to fixed terminals 25 of switch 16. A signal at external input terminal 20 is connected to fixed terminal(s) 26 of selector switch 16. Movable contact 28 is movable to position “A” for selection to internally drive respective loudspeakers 14 from amplifiers 18 through output signal leads 22, 34. Loudspeakers 14 are driven from the signal available at the external input terminal 20 when movable contact 28 is moved to position “B”.

In the exemplary embodiment, the external audio signal reproducing apparatus connectable to terminal 20, is a surround sound system having a center loudspeaker terminal for connection to a loudspeaker to receive a center L+R signal. This center loudspeaker would be disposed between the left and right front stereophonic loudspeakers, e.g., the loudspeaker units of a surround sound system typically are each arranged at a front right position (FR), a front left position (FL), a front center position (FC), a surround right position (SR) and a surround left position (SL) respectively, in a manner known in the art. However, it is within the contemplation of the present invention that loudspeaker(s) 14 can be used in place of any of the loudspeakers of the surround sound system or any other loudspeaker of any other type of sound system depending upon the signal provided at terminal 20. Additionally, since the television receiver has stereo auxiliary audio input terminals 40, the television receiver can provide a stereo expansion effect (not shown) for a stereo signal coupled to such auxiliary input terminals 40 with the movable contact 28 switched in direction “A”.

Thus, loudspeakers 14 connectable to external input terminal 20 of the television receiver 10 in switch position “B”, provides that the speaker system 14 can be commonly used by both the television receiver 10 and the external program source. The speaker system 14 has at least one loudspeaker unit, and in the exemplary embodiment has two loudspeakers because television receiver 10 is a stereophonic sound receiver. If the audio signal is provided by a surround sound audio system, the speaker system 14 can then serve as the front center loudspeaker (FC) as discussed above.

When the two or more loudspeakers 14 are disconnected from their respective amplifier 18 and are connected by switch 16 to terminal 20, the loudspeakers are connected in series with each other, i.e., their impedances are additive. Thus, for an external power amplifier having a transformerless output, which is the case for almost all contemporary audio power amplifiers, the power output is reduced by one half due to the doubling of the load impedance. This has the benefit of permitting the loudspeakers to be powered by an external power amplifier which is rated to be higher in power output than each of power amplifiers 18, so that the loudspeakers will have an improved ability to not be damaged by such exposure to higher power. This has the further benefit that the power rating of the loudspeakers need only to be matched to the power output of their respective amplifier 18, thus permitting the use of less expensive loudspeakers.

It is within the contemplation of the present invention that even though the present amplifiers 18 are alike since they are in the same IC, the amplifiers 18 can have differing output power and be greater in number than just two. Further, even though the present embodiment shows a single input terminal 20, a plurality of input terminals can be used for a plurality of external amplifiers, which need not have identical output power. Obviously, in such cases, switch 16 will change accordingly.

When switch 16 is in the “center” position, i.e., switched in direction “B”, loudspeakers 14 are no longer loading respective amplifiers 18. Accordingly, upon the switching to the “center” position of switch 16, a muting circuit 30 is actuated by switch 16. Muting circuit 30 is actuated in response to the connection of amplifier 18 output line 34 to the muting circuit 30 input line 36 at switch terminal 38. Muting circuit 30 applies a voltage and/or components coupled to ground (not shown), to a muting pin 32 of integrated circuit 33, to mute the integrated circuit or to place it in a standby mode, in a manner known in the art.

Amplifiers 18 are part of a TDA7490 integrated circuit made by STMicroelectronics headquartered in Geneva, Switzerland, and are 25 watt stereo Class D amplifiers. The power supply, oscillator, and high frequency output filters are not shown in the FIGURE and form no part of the present invention.

Switch 16 is a break-before-make slide switch but any other suitable switch can be used, e.g., a toggle switch, a relay.

1. Apparatus for switching a plurality of loudspeakers between amplifiers of differing power output comprising:
first means for coupling a plurality of loudspeakers to a first plurality of power amplifiers having a first power output;
second means for coupling the plurality of loudspeakers to at least one of a second power amplifiers each having a second power output greater than the first power output, and
means for changing the circuit configuration of the plurality of loudspeakers according to the power output of the amplifiers to which the plurality of loudspeakers are coupled.

2. Apparatus for switching a plurality of loudspeakers between amplifiers comprising:
first means for coupling a plurality of loudspeakers to a first plurality of power amplifiers;
second means for coupling the plurality of loudspeakers to at least one of a second power amplifiers, and
means for changing the circuit configuration of the plurality of loudspeakers according to the power output of the amplifiers to which the plurality of loudspeakers are coupled.

3. Apparatus for switching a plurality of loudspeakers between amplifiers comprising:
first means for coupling a plurality of loudspeakers to at least one of a first amplifiers having a first power output;
second means for coupling the plurality of loudspeakers to at least one of a second amplifiers having a second power output, and
means for changing the circuit configuration of the plurality of loudspeakers according to the power output of the amplifiers to which the plurality of loudspeakers are coupled.

4. The apparatus of claim 3 wherein the first power output and the second power output are different, the first power amplifiers are more than one, and the second power amplifiers are more than one.

5. The apparatus of claim 3 wherein the second power output is greater than the first power output.

6. Apparatus for switching a plurality of loudspeakers between amplifiers comprising:
first means for coupling a plurality of loudspeakers in a first circuit configuration to at least one of a first amplifiers having a first power output, and
second means for coupling the plurality of loudspeakers in a second circuit configuration to at least one of a second amplifiers having a second power output.

7. The apparatus of claim 6 wherein the apparatus is a television receiver.

8. The apparatus of claim 6 wherein the individual loudspeakers are rated at a predetermined power, each of the plurality of first power outputs are not the same but are equal to or less than the predetermined power rating of the individual loudspeakers, and each of the plurality of second power outputs are not the same but are greater than the predetermined power rating of the individual loudspeakers.
